(19) United States
(12) Patent Application Publication
(10) Pub. No.: US 2025/0063924 A1
(43) Pub. Date: Feb. 20, 2025

(54) DISPLAY APPARATUS

(71) Applicant: Samsung Display Co., Ltd., Yongin-Si (KR)

(72) Inventors: Yunhee Park, Yongin-si (KR); Kyungseon Tak, Yongin-si (KR); Sujeong Kim, Yongin-si (KR)

(21) Appl. No.: 18/440,974

(22) Filed: Feb. 14, 2024

(30) Foreign Application Priority Data
Aug. 18, 2023 (KR) 10-2023-0108549

(51) Int. Cl. H10K 59/80; H10K 59/38; H10K 59/40

(52) U.S. Cl. CPC H10K 59/8792; H10K 59/38; H10K 59/40

(57) ABSTRACT

Provided is a display apparatus including a light receiving device with improved detection performance. The display apparatus includes a substrate, a first light emitting device and a light receiving device disposed on the substrate and positioned adjacent to each other in a plan view, and a light blocking layer disposed on the first light emitting device and the light receiving device and including a first upper opening vertically aligned with the first light emitting device and a sensing upper opening vertically aligned with the light receiving device, wherein the light blocking layer includes a black pigment and a blue pigment.

### CROSS-REFERENCE TO RELATED APPLICATION

This application is based on and claims priority under 35 U.S.C. § 119 to Korean Patent Application No. 10-2023-0108549 filed on Aug. 18, 2023 in the Korean Intellectual Property Office, the disclosure of which is incorporated by reference herein in its entirety.

### BACKGROUND

### 1. Field

One or more embodiments relate to a display apparatus, and more particularly, to a display apparatus including a light receiving device with improved detection performance.

### 2. Description of the Related Art

Recently, display apparatuses not only provide information to users by using images but also provide users with various functions by organically communicating with the users, such as by detecting a user's input. For this purpose, such display apparatuses also have a function for detecting a user's input. Methods of detecting a user's input include, for example, a capacitive method of detecting a change in the capacitance formed between electrodes, an optical method of detecting incident light by using a light receiving device, and an ultrasonic method of detecting vibrations by using a piezoelectric material.

### SUMMARY

In the display apparatuses of the related art, in the case of the optical method, the light emitted from a light emitting device gets reflected from the lower surface of a light blocking layer onto a light receiving device. The light receiving device treats this incident reflected light as noise in the light receiving device. The perceived extra noise negatively affects the performance of the light receiving device.

One or more embodiments include a display apparatus including a light receiving device with improved detection performance. However, these problems are merely examples and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate, a first light emitting device and a light receiving device disposed on the substrate and arranged adjacent to each other in a plan view, and a light blocking layer disposed on the first light emitting device and the light receiving device and including a first upper opening vertically aligned with the first light emitting device and a sensing upper opening vertically aligned with the light receiving device, wherein the light blocking layer includes a black pigment and a blue pigment.

A weight ratio of the black pigment to the blue pigment may be greater than about 10:0 and less than or equal to about 7:1.

The black pigment may include at least one of a carbon black and an organic black pigment.

The blue pigment may include at least one of C.I. pigment blues 15, 15:1, 15:2, 15:3, 15:4, and 15:6.

The light blocking layer may further include a violet pigment, and the violet pigment may include at least one of C.I. pigment violets 1, 19, 23, 27, 29, 30, 32, 37, 40, 42, and 50.

The display apparatus may further include a touch sensor layer arranged between the first light emitting device and the light receiving device and the light blocking layer and including a plurality of touch conductive patterns and a plurality of touch insulating layers.

A lower surface of the light blocking layer may contact a layer including an inorganic material.

The lower surface of the light blocking layer may contact a touch insulating layer included in the touch sensor layer.

The display apparatus may further include an encapsulation layer arranged between the first light emitting device and the touch sensor layer and including at least one inorganic layer and at least one organic layer.

The display apparatus may further include a first color filter in the first upper opening and a sensing color filter in the sensing upper opening.

The first color filter and the sensing color filter may transmit light in a same wavelength band.

The first color filter and the sensing color filter may transmit light in an about 495 nm to about 580 nm wavelength band.

The display apparatus may further include an auxiliary layer disposed over the light blocking layer and including a first auxiliary opening vertically aligned with the first upper opening and a sensing auxiliary opening vertically aligned with the sensing upper opening.

The auxiliary layer may absorb light in an about 380 nm to about 495 nm wavelength band.

The auxiliary layer may transmit light in an about 495 nm to about 580 nm wavelength band or may transmit light in an about 580 nm to about 780 nm wavelength band.

The first light emitting device may include a pixel electrode, an emission layer disposed on the pixel electrode, and an opposite electrode disposed on the emission layer, and the light receiving device may include a sensing electrode, an active layer disposed on the sensing electrode, and an opposite electrode arranged on the active layer.

The display apparatus may further include a pixel definition layer disposed on the pixel electrode and the sensing electrode and including a first lower opening vertically aligned with the first upper opening and a sensing lower opening vertically aligned with the sensing upper opening.

The display apparatus may further include a second light emitting device and a third light emitting device disposed on the substrate, and the first light emitting device, the second light emitting device, and the third light emitting device may be positioned apart from each other in a plan view.

The first light emitting device may emit light in an about 495 nm to about 580 nm wavelength band, the second light emitting device may emit light in an about 380 nm to about 495 nm wavelength band, the third light emitting device may emit light in an about 580 nm to about 780 nm wavelength band, and the light receiving device may detect light in an about 495 nm to about 580 nm wavelength band.

The display apparatus may further include a cover window disposed on the light blocking layer.

Other aspects, features, and advantages other than those described above will become apparent from the following detailed description, the appended claims, and the accompanying drawings.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view schematically illustrating a portion of a display apparatus according to an embodiment;

FIG. 2 is an equivalent circuit diagram of a pixel circuit electrically connected to a light emitting device included in a pixel of the display apparatus of FIG. 1;

FIG. 3 is an enlarged plan view schematically illustrating a region A of the display apparatus of FIG. 1;

FIG. 4 is a schematic cross-sectional view of a display apparatus according to an embodiment;

FIG. 5 is a cross-sectional view schematically illustrating a cross-section of the display apparatus of FIG. 3 taken along line I-I′;

FIG. 6 is a diagram for describing an optical path of a light reflected at the interface of a light blocking layer of a display apparatus according to a comparative example;

FIG. 7 is a graph illustrating the reflectance of a light blocking layer depending on the weight ratio of a black pigment to a blue pigment included in the light blocking layer;

FIG. 8A is a micrograph of a light blocking layer when the weight ratio of a black pigment to a blue pigment included in the light blocking layer is 7:3;

FIG. 8B is a micrograph of a light blocking layer when the weight ratio of a black pigment to a blue pigment included in the light blocking layer is 6:4; and

FIG. 9 is a cross-sectional view schematically illustrating a portion of a display apparatus according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may include various embodiments and modifications, and particular embodiments thereof are illustrated in the drawings and will be described herein in detail. The effects and features of the disclosure and the accomplishing methods thereof will become apparent from the embodiments described below in detail with reference to the accompanying drawings. However, the disclosure is not limited to the embodiments described below, and may be embodied in various modes.

It will be understood that although terms such as “first” and “second” may be used herein to describe various elements, these elements should not be limited by these terms and these terms are only used to distinguish one element from another element.

As used herein, the singular forms “a,” “an,” and “the” are intended to include the plural forms as well, unless the context clearly indicates otherwise.

Also, it will be understood that the terms “comprise,” “include,” and “have” used herein specify the presence of stated features or components, but do not preclude the presence or addition of one or more other features or components.

As used herein, “A and/or B” represents the case of A, B, or A and B. Also, “at least one of A and B” represents the case of A, B, or A and B.

It will be understood that when an element such as a layer, a region, or a plate is referred to as being “on” another element, it may be “directly on” the element or may be “indirectly on” the other element with one or more intervening elements therebetween.

It will be understood that when a layer, region, or component is referred to as being “connected to” another layer, region, or component, it may be “directly connected to” the other layer, region, or component or may be “indirectly connected to” the other layer, region, or component with one or more intervening layers, regions, or components therebetween. For example, it will be understood that when a layer, region, or component is referred to as being “electrically connected to” another layer, region, or component, it may be “directly electrically connected to” the other layer, region, or component and/or may be “indirectly electrically connected to” the other layer, region, or component with one or more intervening layers, regions, or components therebetween.

As used herein, the x axis, the y axis, and the z axis are not limited to three axes of the rectangular coordinate system, and may be interpreted in a broader sense. For example, the x axis, the y axis, and the z axis may be perpendicular to one another or may represent different directions that are not perpendicular to one another.

Herein, “in a plan view” may mean when a target portion is viewed from above. That is, herein, “in a plan view” may mean the case of being viewed in a direction perpendicular to a substrate 100. For example, “A and B spaced apart from each other in the plan view” may mean “A and B spaced apart from each other when viewed in a direction perpendicular to the substrate 100.”

Hereinafter, embodiments will be described in detail with reference to the accompanying drawings, and in the following description, like reference numerals will denote like elements and redundant descriptions thereof will be omitted for conciseness. Sizes of components in the drawings may be exaggerated for convenience of description. In other words, because the sizes and shapes of components in the drawings are arbitrarily illustrated for convenience of description, the disclosure is not limited thereto.

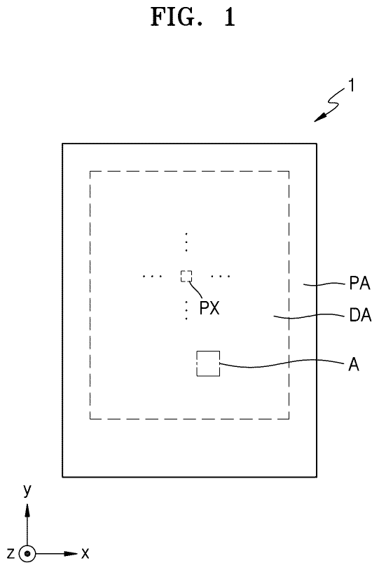

FIG. 1 is a plan view schematically illustrating a portion of a display apparatus 1 according to an embodiment. FIG. 1, as well as other figures of this disclosure, include a coordinate system. As used herein, an “x direction” refers to the direction indicated by the arrow pointing in the x direction, and “−x direction” refers to the opposite direction of the arrow on the same x-axis. Same convention applies to “y direction,” “−y direction,” “z direction,” and “−z direction.”

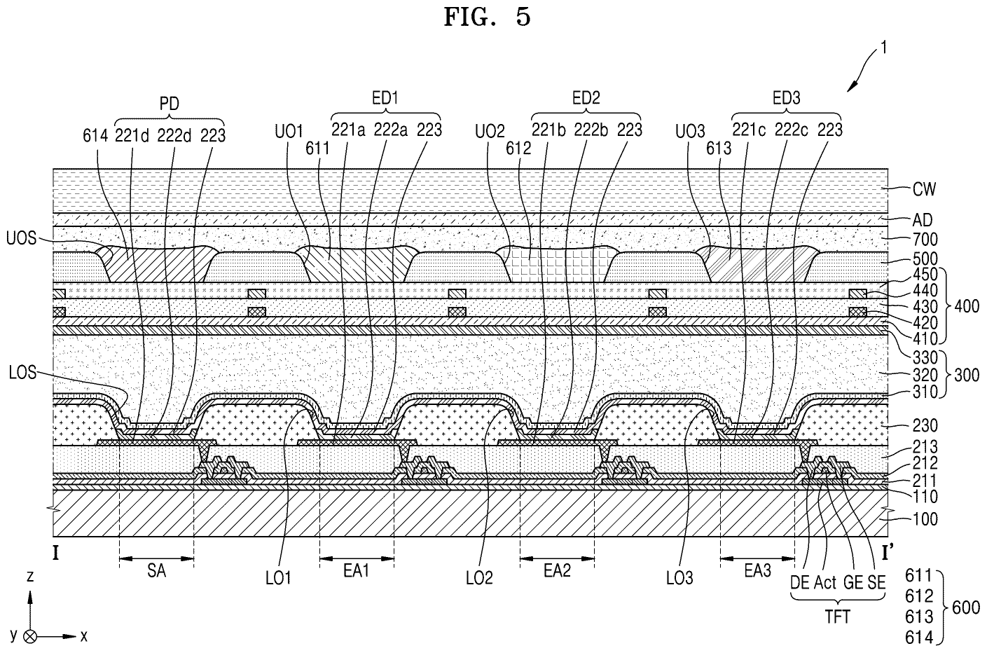

As illustrated in FIG. 1, the display apparatus 1 may include a display area DA in which a plurality of pixels PX are arranged and a peripheral area PA located outside the display area DA. Particularly, the peripheral area PA may entirely surround the display area DA. It may be understood that a substrate 100 (see FIG. 5) included in a display apparatus includes a display area DA and a peripheral area PA.

Each pixel PX of the display apparatus 1 may be an area capable of emitting light of a certain color, and the display apparatus 1 may provide an image by using light emitted from the pixels PX. For example, each pixel PX may emit green, blue, or red light.

The display area DA may have a polygonal shape such as a tetragonal shape as illustrated in FIG. 1. For example, the display area DA may have a rectangular shape in which the vertical length is greater than the horizontal length, may have a rectangular shape in which the horizontal length is greater than the vertical length, or may have a square shape. Alternatively, the display area DA may have various shapes such as an elliptical shape or a circular shape.

The peripheral area PA may be a non-display area in which pixels are not arranged. The peripheral area PA may entirely surround the display area DA. A driver or the like for providing an electrical signal or power to the pixels PX may be arranged in the peripheral area PA. The peripheral area PA may include pads to which various electronic devices, printed circuit boards, or the like may be electrically connected.

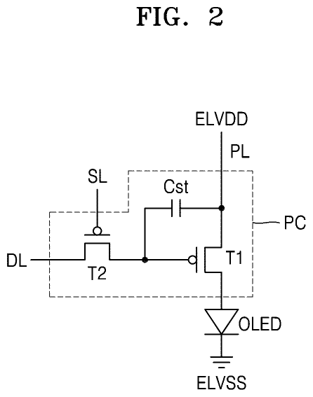

FIG. 2 is an equivalent circuit diagram of a pixel circuit PC electrically connected to a light emitting device included in a pixel PX of the display apparatus 1 of FIG. 1. For example, the light emitting device may be an organic light emitting diode OLED.

The pixel circuit PC may include a first transistor T1, a second transistor T2, and a storage capacitor Cst. As a switching transistor, the second transistor T2 may be connected to a scan line SL and a data line DL and may be turned on by a switching signal input from the scan line SL to transmit a data signal input from the data line DL to the first transistor T1. One end of the storage capacitor Cst may be electrically connected to the second transistor T2 and the other end thereof may be electrically connected to a driving voltage line PL, and the storage capacitor Cst may be configured to store a voltage corresponding to the difference between a voltage received from the second transistor T2 and a driving power voltage ELVDD supplied to the driving voltage line PL.

As a driving transistor, the first transistor T1 may be connected to the driving voltage line PL and the storage capacitor Cst and may be configured to control a driving current flowing from the driving voltage line PL through the light emitting device in response to a voltage value stored in the storage capacitor Cst. The light emitting device may emit light with a certain brightness according to the driving current. An opposite electrode 223 (see FIG. 5) of the light emitting device may be supplied with an electrode power voltage ELVSS.

Although FIG. 2 illustrates that the pixel circuit PC includes two transistors and one storage capacitor, the disclosure is not limited thereto. The number of transistors and the number of storage capacitors may be variously modified according to the design of the pixel circuit PC.

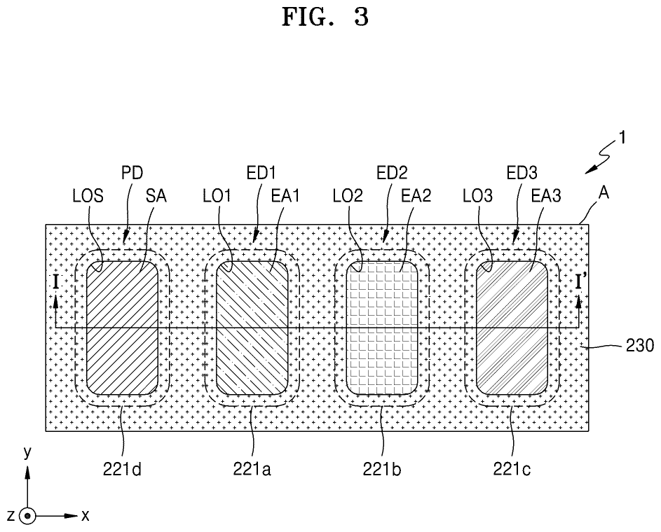

FIG. 3 is an enlarged plan view schematically illustrating a region A of the display apparatus 1 of FIG. 1. For convenience, FIG. 3 illustrates a plan view over a pixel definition layer 230.

As illustrated in FIG. 3, the display apparatus 1 may include a plurality of light emitting devices and a light receiving device PD. The plurality of light emitting devices may include a first light emitting device ED1, a second light emitting device ED2, and a third light emitting device ED3. The first light emitting device ED1, the second light emitting device ED2, and the third light emitting device ED3 may emit light of different colors. For example, the first light emitting device ED1 may emit green light, the second light emitting device ED2 may emit blue light, and the third light emitting device ED3 may emit red light. The green light may be light belonging to a wavelength band of about 495 nm to about 580 nm, the blue light may be light belonging to a wavelength band of about 380 nm to about 495 nm, and the red light may be light belonging to a wavelength band of about 580 nm to about 780 nm.

The light receiving device PD may detect the light emitted from the first light emitting device ED1, the second light emitting device ED2, or the third light emitting device ED3 and then reflected by an object. For example, the green light emitted by the first light emitting device ED1 may be reflected by an object contacting a cover window toward the light receiving device PD, causing the light receiving device PD to detect the incident green light. Thus, the display apparatus 1 may sense the object.

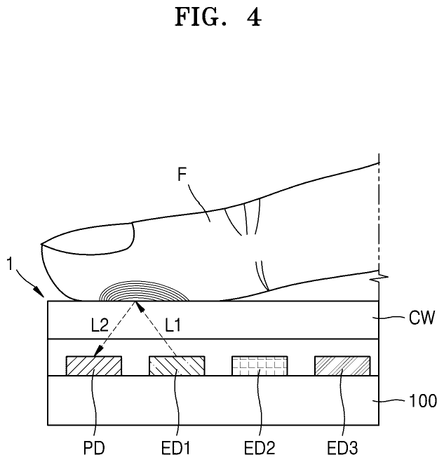

Particularly, as illustrated in FIG. 4 that is a schematic cross-sectional view of a display apparatus 1 according to an embodiment, a first light emitting device ED1, a second light emitting device ED2, a third light emitting device ED3, and a light receiving device PD may be disposed over a substrate 100 of the display apparatus 1, and a cover window CW may be disposed over the first light emitting device ED1, the second light emitting device ED2, the third light emitting device ED3, and the light receiving device PD. Light L1 emitted from the first light emitting device ED1 of the display apparatus 1 may be reflected from an object contacting the cover window CW of the display apparatus 1, for example, from the fingerprint of a finger F. Light L2 reflected from the fingerprint of the finger F may be incident on the light receiving device PD of the display apparatus 1. Accordingly, the light receiving device PD may detect the light L2 reflected by the object. This way, the display apparatus 1 may sense the object.

Each light emitting device may include a pixel electrode, an opposite electrode, and an emission layer arranged therebetween, and the light receiving device may include a sensing electrode, an opposite electrode, and an active layer arranged therebetween. Accordingly, the first light emitting device ED1 may include a first pixel electrode 221a, the second light emitting device ED2 may include a second pixel electrode 221b, the third light emitting device ED3 may include a third pixel electrode 221c, and the light receiving device PD may include a sensing electrode 221d.

The first pixel electrode 221a, the second pixel electrode 221b, the third pixel electrode 221c, and the sensing electrode 221d may be arranged apart from each other in the plan view. The first pixel electrode 221a, the second pixel electrode 221b, the third pixel electrode 221c, and the sensing electrode 221d may have the same size as illustrated in FIG. 3. Alternatively, in another embodiment, the first pixel electrode 221a, the second pixel electrode 221b, and the third pixel electrode 221c may have different sizes.

The pixel definition layer 230 may be disposed over the first pixel electrode 221a, the second pixel electrode 221b, the third pixel electrode 221c, and the sensing electrode 221d. The pixel definition layer 230 may define a first lower opening LO1, a second lower opening LO2, a third lower opening LO3, and a sensing lower opening LOS. The first lower opening LO1 and the second lower opening LO2 may be located adjacent to each other in a first direction (e.g., the x direction or the −x direction), and the third lower opening LO3 may be located across the second lower opening LO2 from the first lower opening LO1 such that the second lower opening LO2 is between the first lower opening LO1 and the third lower opening LO3. The sensing lower opening LOS may be located adjacent to the first lower opening LO1 in the first direction (e.g., the x direction or the −x direction). That is, the sensing lower opening LOS may be located across the first lower opening LO1 from the second lower opening LO2 such that the first lower opening LO1 is between the sensing lower opening LOS and the second lower opening LO2.

The first lower opening LO1 may expose a center portion of the first pixel electrode 221a, the second lower opening LO2 may expose a center portion of the second pixel electrode 221b, and the third lower opening LO3 may expose a center portion of the first pixel electrode 221a. The sensing lower opening LOS may expose a center portion of the sensing electrode 221d. The first lower opening LO1, the second lower opening LO2, the third lower opening LO3, and the sensing lower opening LOS may have the same size as illustrated in FIG. 3. Alternatively, in another embodiment, some of the first lower opening LO1, the second lower opening LO2, the third lower opening LO3, and the sensing lower opening LOS may have different sizes.

Although not illustrated in FIG. 3, emission layers emitting light may be respectively located in the first lower opening LO1, the second lower opening LO2, and the third lower opening LO3 of the pixel definition layer 230, and an active layer detecting light may be located in the sensing lower opening LOS of the pixel definition layer 230. The opposite electrode may be disposed over the emission layers and the active layer. The opposite electrode may be continuously disposed across the first pixel electrode 221a, the second pixel electrode 221b, the third pixel electrode 221c, and the sensing electrode 221d.

The stack structure of the pixel electrode, the emission layer, and the opposite electrode may form one light emitting device. Also, as described above, the stack structure of the sensing electrode, the active layer, and the opposite electrode may form one light receiving device. One opening of the pixel definition layer 230 may correspond to one light emitting device and may define one emission area. Alternatively, one opening of the pixel definition layer 230 may correspond to one light receiving device and may define one sensing area.

For example, an emission layer emitting green light may be arranged in the first lower opening LO1, and the first lower opening LO1 may define a first emission area EA1. Similarly, an emission layer emitting blue light may be arranged in the second lower opening LO2, and the second lower opening LO2 may define a second emission area EA2. Similarly, an emission layer emitting red light may be arranged in the third lower opening LO3, and the third lower opening LO3 may define a third emission area EA3. An active layer detecting light may be arranged in the sensing lower opening LOS, and the sensing lower opening LOS may define a sensing area SA.

Accordingly, the area of the first lower opening LO1 on the first electrode 221a may be equal to the area of the first emission area EA1. The area of the second lower opening LO2 may be equal to the area of the second emission area EA2, and the area of the third lower opening LO3 may be equal to the area of the third emission area EA3. The area of the sensing lower opening LOS may be equal to the area of the sensing area SA. The “area” of a lower opening, as used herein, refers to the area of the pixel electrodes (221a, 221b, and 221c) that is not covered by the pixel defining layer 230 measured in the x-y plane.

Each of the first lower opening LO1, the second lower opening LO2, the third lower opening LO3, and the sensing lower opening LOS may have a polygonal shape when viewed in a direction (the z-axis direction) perpendicular to the substrate 100 (see FIG. 5). In other words, each of the first emission area EA1, the second emission area EA2, the third emission area EA3, and the sensing area SA have a polygonal shape when viewed in a direction (the z-axis direction) perpendicular to the substrate 100. FIG. 3 illustrates that each of the first emission area EA1, the second emission area EA2, the third emission area EA3, and the sensing area SA has a rectangular shape, particularly a rectangular shape with rounded corners, when viewed in a direction (the z-axis direction) perpendicular to the substrate 100. However, the disclosure is not limited thereto. For example, each of the first emission area EA1, the second emission area EA2, the third emission area EA3, and the sensing area SA may have a circular shape or an elliptical shape when viewed in a direction (the z-axis direction) perpendicular to the substrate 100.

FIG. 5 is a cross-sectional view schematically illustrating a cross-section of the display apparatus 1 taken along line I-I′ of FIG. 3. As illustrated in FIG. 5, the display apparatus 1 may include a substrate 100, a transistor TFT, a first light emitting device ED1, a second light emitting device ED2, a third light emitting device ED3, a light receiving device PD, an encapsulation layer 300, a touch sensor layer 400, a light blocking layer 500, a color filter layer 600, a color filter planarization layer 700, an adhesive member AD, and a cover window CW.

The substrate 100 may include various materials having flexible or bendable characteristics. For example, the substrate 100 may include glass, metal, or polymer resin. Also, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. However, the substrate 100 may be variously modified such as including a multilayer structure including two layers including the polymer resin and a barrier layer arranged between the two layers and including an inorganic material (e.g., silicon oxide (SiOₓ), silicon nitride (SiNₓ), or silicon oxynitride (SiOₓN_{y})).

A light emitting device and a transistor TFT electrically connected to the light emitting device may be disposed over the substrate 100. For example, the first light emitting device ED1, the second light emitting device ED2, and the third light emitting device ED3 may be disposed over the substrate 100. One light emitting device may correspond to one pixel PX. For example, the light emitting device may be an organic light emitting diode OLED. Moreover, a light receiving device PD and a transistor TFT electrically connected to the light receiving device PD may be disposed over the substrate 100.

Particularly, a plurality of transistors TFT may be disposed over the substrate 100. Each of the plurality of transistors TFT may be electrically connected to the first light emitting device ED1, the second light emitting device ED2, the third light emitting device ED3, or the light receiving device PD. The transistor TFT electrically connected to each light emitting device may be the transistor included in the pixel circuit PC described above with reference to FIG. 2. Some of the plurality of transistors TFT disposed over the substrate 100 may be electrically connected to the light receiving device PD. Some of the plurality of transistors TFT disposed over the substrate 100 may be electrically connected to the sensing electrode 221d of the light receiving device PD to drive the light receiving device PD.

Because the structures of the plurality of transistors TFT connected to the first light emitting device ED1, the second light emitting device ED2, the third light emitting device ED3, or the light receiving device PD may be the same or similar to each other, the following description will focus on one transistor TFT.

A buffer layer 110 including an inorganic material such as silicon oxide (SiOₓ), silicon nitride (SiNₓ), and/or silicon oxynitride (SiOₓN_{y}) may be arranged between the transistor TFT and the substrate 100. The buffer layer 110 may function to increase the smoothness of the upper surface of the substrate 100 or to prevent or minimize the penetration of impurities into a semiconductor layer Act of the transistor TFT from the substrate 100 or the like.

As illustrated in FIG. 5, the transistor TFT may include a semiconductor layer Act, a gate electrode GE, a source electrode SE, and a drain electrode DE. FIG. 5 illustrates a top gate type in which the gate electrode GE is disposed over the semiconductor layer Act with a gate insulating layer 211 therebetween; however, the disclosure is not limited thereto. For example, the transistor TFT may be of a bottom gate type.

The semiconductor layer Act may be located over the buffer layer 110. The semiconductor layer Act may include a channel area, and a source area and a drain area on both sides of the channel area that are doped with dopants. In this case, the dopants may include N-type dopants or P-type dopants. The semiconductor layer Act may include amorphous silicon or polysilicon. In an embodiment, the semiconductor layer Act may include an oxide of at least one of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). Also, the semiconductor layer Act may include a Zn oxide-based material such as a Zn oxide, an In—Zn oxide, or a Ga—In—Zn oxide. Also, the semiconductor layer Act may include an In—Ga—Zn—O (IGZO), In—Sn—Zn—O (ITZO), or In—Ga—Sn—Zn—O (IGTZO) semiconductor containing a metal such as indium (In), gallium (Ga), or stannum (Sn) in ZnO.

The gate electrode GE may be positioned over the semiconductor layer Act to at least partially overlap the semiconductor layer Act. Particularly, the gate electrode GE may overlap the channel area of the semiconductor layer Act. The gate electrode GE may include various conductive materials including molybdenum (Mo), aluminum (Al), copper (Cu), titanium (Ti), or the like and may have various layer structures. For example, the gate electrode GE may include a Mo layer and an Al layer or may have a multilayer structure of a Mo layer/an Al layer/a Mo layer. Also, the gate electrode GE may have a multilayer structure including an ITO layer covering a metal material.

The gate insulating layer 211 between the semiconductor layer Act and the gate electrode GE may include an inorganic insulating material such as silicon oxide, silicon nitride, silicon oxynitride, aluminum oxide, titanium oxide, tantalum oxide, or hafnium oxide. The gate insulating layer 211 may include a single layer or multiple layers including the above material.

The source electrode SE and the drain electrode DE may be connected to the source area and the drain area of the semiconductor layer Act through a contact hole. The source electrode SE and the drain electrode DE may include various conductive materials including molybdenum (Mo), aluminum (Al), copper (Cu), titanium (Ti), or the like and may have various layer structures. For example, the source electrode SE and the drain electrode DE may include a Ti layer and/or an Al layer or may have a multilayer structure of a Ti layer/an Al layer/a Ti layer. Also, the source electrode SE and the drain electrode DE may have a multilayer structure including an ITO layer covering a metal material.

An interlayer insulating layer 212 may include an inorganic insulating material such as silicon oxide, silicon nitride, silicon oxynitride, aluminum oxide, titanium oxide, tantalum oxide, or hafnium oxide. Also, the interlayer insulating layer 212 may include a single layer or multiple layers including the above material.

Moreover, the gate insulating layers 211 and the interlayer insulating layer 212 including the inorganic material described above may be formed through chemical vapor deposition (CVD), atomic layer deposition (ALD), or the like; however, the disclosure is not limited thereto.

The transistor TFT may be covered by an organic insulating layer 213. For example, the organic insulating layer 213 may cover the source electrode SE and the drain electrode DE. The organic insulating layer 213 may be a planarization insulating layer and may include a substantially flat upper surface. The organic insulating layer 213 may include an organic insulating material such as a general-purpose polymer such as polymethylmethacrylate (PMMA) or polystyrene (PS), a polymer derivative having a phenolic group, an acrylic polymer, an imide-based polymer, an arylether-based polymer, an amide-based polymer, a fluorine-based polymer, a p-xylene-based polymer, a vinyl alcohol-based polymer, or any blend thereof. In an embodiment, the organic insulating layer 213 may include polyimide.

Over the organic insulating layer 213, the first light emitting device ED1, the second light emitting device ED2, and the third light emitting device ED3 may be arranged apart from each other. The light receiving device PD may be arranged adjacent to the first light emitting device ED1. Particularly, the first light emitting device ED1 and the second light emitting device ED2 adjacent to each other in the first direction (e.g., the x direction or the −x direction) may be disposed over the organic insulating layer 213, and the light emitting device ED3 may be disposed over the organic insulating layer 213 to be adjacent to the second light emitting device ED2 in the first direction (e.g., the x direction or the −x direction). That is, the third light emitting device ED3 may be disposed on the organic insulating layer 213 to be located across the second light emitting device ED2 from the first light emitting device ED1, such that the second light emitting device ED2 is between the third light emitting device ED3 and the first light emitting device ED1. The first light emitting device ED1, the second light emitting device ED2, and the third light emitting device ED3 may be positioned apart from each other in the plan view.

Over the organic insulating layer 213, the first light emitting device ED1 and the light receiving device PD may be arranged adjacent to each other in the first direction (e.g., the x direction or the −x direction). That is, the light receiving device PD may be disposed on the organic insulating layer 213 to be located across the first light emitting device ED1 from the second light emitting device ED2, such that the first light emitting device ED1 is between the light receiving device PD and the second light emitting device ED2. In other words, the first light emitting device ED1 and the light receiving device PD may be arranged adjacent to each other in the plan view.

The first light emitting device ED1, the second light emitting device ED2, and the third light emitting device ED3 may emit light of different colors. The light receiving device PD may detect the light that is emitted from the first light emitting device ED1, the second light emitting device ED2, or the third light emitting device ED3 and reflected by an object. For example, the first light emitting device ED1 may emit green light, the second light emitting device ED2 may emit blue light, and the third light emitting device ED3 may emit red light. The light receiving device PD may detect the green light that was originally emitted from the first light emitting device ED1 and then reflected by the object.

The first light emitting device ED1 may include a first pixel electrode 221a, a first emission layer 222a, and an opposite electrode 223. The second light emitting device ED2 may include a second pixel electrode 221b, a second emission layer 222b, and an opposite electrode 223, and the third light emitting device ED3 may include a third pixel electrode 221c, a third emission layer 222c, and an opposite electrode 223. The light receiving device PD may include a sensing electrode 221d, an active layer 222d, and an opposite electrode 223. The opposite electrode 223 may be continuously disposed over the entire surface of the display apparatus 1 and accordingly may be shared by a plurality of light emitting devices and a light receiving device.

The first pixel electrode 221a, the second pixel electrode 221b, and the third pixel electrode 221c may be arranged apart from each other over the organic insulating layer 213. The sensing electrode 221d may be disposed over the organic insulating layer 213 to be adjacent to the first pixel electrode 221a.

Particularly, the second pixel electrode 221b may be arranged over the organic insulating layer 213 to be adjacent to the first pixel electrode 221a in the first direction (e.g., the x direction or the −x direction). The third pixel electrode 221c may be disposed over the organic insulating layer 213 to be adjacent to the second pixel electrode 221b in the first direction (e.g., the x-axis direction). That is, the third pixel electrode 221c may be disposed on the organic insulating layer 213 to be located across the second pixel electrode 221b from the first pixel electrode 221a, such that the second pixel electrode 221b is between the third pixel electrode 221c and the first pixel electrode 221a. The sensing electrode 221d may be disposed over the organic insulating layer 213 to be adjacent to the first pixel electrode 221a in the first direction (e.g., the x-axis direction). That is, the sensing electrode 221d may be disposed on the organic insulating layer 213 to be located across the first pixel electrode 221a from the second pixel electrode 221b, such that the first pixel electrode 221a is between the sensing electrode 221d and the second pixel electrode 221b.

The first pixel electrode 221a, the second pixel electrode 221b, the third pixel electrode 221c, and the sensing electrode 221d may include a transparent conductive layer formed of a transparent conductive oxide such as ITO, In₂O₃, or IZO, and a reflective layer formed of a metal such as Al or Ag. For example, the first pixel electrode 221a, the second pixel electrode 221b, the third pixel electrode 221c, and the sensing electrode 221d may have a three-layer structure of ITO/Ag/ITO.

As illustrated in FIG. 5, the first pixel electrode 221a, the second pixel electrode 221b, the third pixel electrode 221c, and the sensing electrode 221d may be electrically connected to the transistor TFT by contacting any one of the source electrode SE and the drain electrode DE. Particularly, each of the first pixel electrode 221a, the second pixel electrode 221b, the third pixel electrode 221c, and the sensing electrode 221d may contact any one of the source electrode SE and the drain electrode DE through a contact hole formed in the organic insulating layer 213.

A pixel definition layer 230 may be disposed over the organic insulating layer 213. The pixel definition layer 230 may define a pixel by including an opening corresponding to the pixel, that is, an opening through which at least a portion of the pixel electrode is exposed. Particularly, the pixel definition layer 230 may include a first lower opening LO1, a second lower opening LO2, and a third lower opening LO3. The first lower opening LO1 may expose a portion of the first pixel electrode 221a, the second lower opening LO2 may expose a portion of the second pixel electrode 221b, and the third lower opening LO3 may expose a portion of the third pixel electrode 221c. The exposed portions of the pixel electrodes 221a, 221b, 221c usually include the center portions of the respective pixel electrodes 221a, 221b, 221c. The pixel definition layer 230 may further include a sensing lower opening LOS. The sensing lower opening LOS may expose a portion, e.g., a center portion, of the sensing electrode 221d.

Also, in the case illustrated in FIG. 5, the pixel definition layer 230 may increase the distance between the edge of the first pixel electrode 221a and the opposite electrode 223 over the first pixel electrode 221a. Similarly, the pixel definition layer 230 may increase the distance between the edge of the second pixel electrode 221b and the opposite electrode 223 and may increase the distance between the edge of the third pixel electrode 221c and the opposite electrode 223. The pixel definition layer 230 may increase the distance between the edge of the sensing electrode 221d and the opposite electrode 223. The distance helps prevent occurrence of an arc or the like at the edge of the first pixel electrode 221a, the edge of the second pixel electrode 221b, the edge of the third pixel electrode 221c, or the edge of the sensing electrode 221d. The pixel definition layer 230 may include, for example, an organic material such as polyimide or hexamethyldisiloxane (HMDSO).

The first emission layer 222a may be disposed over the first pixel electrode 221a. The second emission layer 222b may be disposed over the second pixel electrode 221b, and the third emission layer 222c may be disposed over the third pixel electrode 221c. The active layer 222d may be disposed over the sensing electrode 221d. In other words, the first emission layer 222a may be arranged in the first lower opening LO1. The second emission layer 222b may be arranged in the second lower opening LO2, and the third emission layer 222c may be arranged in the third lower opening LO3. The active layer 222d may be arranged in the sensing lower opening LOS.

The first emission layer 222a, the second emission layer 222b, and the third emission layer 222c may include an organic material including a fluorescent or phosphorescent material emitting green, blue, or red light. Each of the first emission layer 222a, the second emission layer 222b, and the third emission layer 222c may be an organic emission layer including a low molecular weight organic material or a high molecular weight organic material. For example, each of the first emission layer 222a, the second emission layer 222b, and the third emission layer 222c may be an organic emission layer and may include copper phthalocyanine, tris-8-hydroxyquinoline aluminum, a poly-phenylenevinylene (PPV)-based material, or a polyfluorene-based material.

In an embodiment, the first emission layer 222a, the second emission layer 222b, and the third emission layer 222c may include a host material and a dopant material. The dopant material may be a material emitting light of a particular color and may include a light emitting material. The light emitting material may include at least one of a phosphorescent dopant, a fluorescent dopant, and a quantum dot. The host material may be a main material of the first emission layer 222a, the second emission layer 222b, and the third emission layer 222c and may be a material that assists the dopant material to emit light.

The active layer 222d may receive light from the outside, generate excitons, and then separate the generated excitons into holes and electrons. When a positive (+) potential is applied to the sensing electrode 221d and a negative (−) potential is applied to the opposite electrode 223, the holes separated in the active layer 222d may move toward the opposite electrode 223 and the electrons separated in the active layer 222d may move toward the sensing electrode 221d. Thus, a photocurrent may be formed in the direction from the sensing electrode 221d to the opposite electrode 223. When a bias is applied between the sensing electrode 221d and the opposite electrode 223, a dark current may flow in the light receiving device PD. Also, when light is incident on the light receiving device PD, a photocurrent may flow in the light receiving device PD. In an embodiment, the light receiving device PD may detect the amount of light from the ratio between the photocurrent and the dark current.

The active layer 222d may include a p-type organic semiconductor and an n-type organic semiconductor. In this case, the p-type organic semiconductor may act as an electron donor, and the n-type organic semiconductor may act as an electron acceptor. In an embodiment, the active layer 222d may be a mixed layer including a p-type organic semiconductor and an n-type organic semiconductor. In this case, the active layer 222d may be formed by co-depositing a p-type organic semiconductor and an n-type organic semiconductor. When the active layer 222d is a mixed layer, excitons may be generated in the diffusion length from the donor-acceptor interface.

In an embodiment, the p-type organic semiconductor may be a compound that acts as an electron donor to supply electrons. For example, the p-type organic semiconductor may include, but is not limited to, boron subphthalocyanine chloride (SubPc), copper (II) phthalocyanine (CuPc), tetraphenyldibenzoferiplanthene (DBP), or any combination thereof. In an embodiment, the n-type organic semiconductor may be a compound that acts as an electron acceptor to accept electrons. For example, the n-type organic semiconductor may include, but is not limited to, C60 fullerene, C70 fullerene, or any combination thereof.

The opposite electrode 223 may be disposed over the first emitting layer 222a, the second emitting layer 222b, the third emitting layer 222c, and the active layer 222d. The opposite electrode 223 disposed over the first emission layer 222a, the second emission layer 222b, the third emission layer 222c, and the active layer 222d may be continuously and integrally formed. However, a portion of the opposite electrode 223 disposed over the active layer 222d may be referred to as a sensing opposite electrode. The opposite electrode 223 may be a transparent electrode or a reflective electrode. In an embodiment, the opposite electrode 223 may include a transparent or semitransparent electrode and may include a thin metal layer having a low work function and including Li, Ca, LiF/Ca, LiF/Al, Al, Ag, Mg, or any compound thereof. Also, in addition to the thin metal layer, the opposite electrode 223 may further include a transparent conductive oxide (TCO) layer such as ITO, IZO, ZnO, or In₂O₃.

The encapsulation layer 300 may be disposed over the first light emitting device ED1, the second light emitting device ED2, the third light emitting device ED3, and the light receiving device PD. For example, the encapsulation layer 300 may be disposed over the opposite electrode 223. Because a light emitting device and a light receiving device may be easily damaged by external moisture or oxygen or the like, the encapsulation layer 300 may cover and protect the light emitting device and the light receiving device.

The encapsulation layer 300 may include at least one inorganic encapsulation layer and at least one organic encapsulation layer. In an embodiment, as illustrated in FIG. 5, the encapsulation layer 300 may include a first inorganic encapsulation layer 310, an organic encapsulation layer 320, and a second inorganic encapsulation layer 330 that are sequentially stacked.

The first inorganic encapsulation layer 310 may cover the opposite electrode 223 and may include silicon oxide (SiOₓ), silicon nitride (SiNₓ), and/or silicon oxynitride (SiOₓN_{y}). When necessary, other layers such as a capping layer may be arranged between the first inorganic encapsulation layer 310 and the opposite electrode 223. Because the first inorganic encapsulation layer 310 is formed along a structure thereunder, the upper surface thereof may not be flat as illustrated in FIG. 5. The organic encapsulation layer 320 may cover the first inorganic encapsulation layer 310 and may have a substantially flat upper surface unlike the first inorganic encapsulation layer 310. Particularly, the upper surface of the organic encapsulation layer 320 may be substantially flat at a portion corresponding to the display area DA. The organic encapsulation layer 320 may include at least one of polyethylene terephthalate, polyethylene naphthalate, polycarbonate, polyimide, polyethylene sulfonate, polyoxymethylene, polyarylate, and hexamethyldisiloxane. The second inorganic encapsulation layer 330 may cover the organic encapsulation layer 320 and may include silicon oxide (SiOₓ), silicon nitride (SiNₓ), and/or silicon oxynitride (SiOₓN_{y}). The second inorganic encapsulation layer 330 may contact the first inorganic encapsulation layer 310 at the edge thereof located outside the display area DA and thus the organic encapsulation layer 320 may not be exposed to the outside.

When the encapsulation layer 300 includes the first inorganic encapsulation layer 310, the organic encapsulation layer 320, and the second inorganic encapsulation layer 330, even when a crack occurs in the encapsulation layer 300, the crack may not be connected between the first inorganic encapsulation layer 310 and the organic encapsulation layer 320 or between the organic encapsulation layer 320 and the second inorganic encapsulation layer 330. Accordingly, the formation of a path through which external moisture or oxygen or the like penetrates into the display area DA may be prevented or minimized.

The touch sensor layer 400 may be disposed over the encapsulation layer 300. Particularly, the touch sensor layer 400 may be disposed over the second inorganic encapsulation layer 330. In other words, the touch sensor layer 400 may be arranged between the first light emitting device ED1, the second light emitting device ED2, the third light emitting device ED3, and the light receiving device PD and the light blocking layer 500, and the encapsulation layer 300 may be arranged between the first light emitting device ED1, the second light emitting device ED2, the third light emitting device ED3, and the light receiving device PD and the touch sensor layer 400. The touch sensor layer 400 may be configured to obtain coordinate information according to an external input, for example, a touch event. The input sensor layer 400 may be configured to obtain coordinate information according to an external input, for example, a touch event of an object such as a finger or a stylus pen.

The touch sensor layer 400 may include a plurality of touch conductive patterns and a plurality of touch insulating layers. For example, the touch sensor layer 400 may include a first touch insulating layer 410, a first touch conductive pattern 420, a second touch insulating layer 430, a second touch conductive pattern 440, and a third touch insulating layer 450. In an embodiment, the first touch insulating layer 410 may include a single layer or multiple layers including an inorganic material such as silicon nitride (SiNₓ), silicon oxide (SiOₓ), and/or silicon oxynitride (SiOₓN_{y}). In some embodiments, the first touch insulating layer 410 may include an organic material. In some embodiments, the first touch insulating layer 410 may be omitted.

The first touch conductive pattern 420 may be disposed over the first touch insulating layer 410 and/or the second inorganic encapsulation layer 330. In an embodiment, the first touch conductive pattern 420 may overlap the pixel definition layer 230. The first touch conductive pattern 420 may not overlap the openings of the pixel definition layer 230. The first touch conductive pattern 420 may include a conductive material. For example, the first touch conductive pattern 420 may include molybdenum (Mo), aluminum (Al), copper (Cu), titanium (Ti), or the like and may include a single layer or multiple layers including the above material. In an embodiment, the first touch conductive pattern 420 may have a structure (Ti/Al/Ti) in which a titanium layer, an aluminum layer, and a titanium layer are sequentially stacked.

The second touch insulating layer 430 may cover the first touch conductive pattern 420. The second touch insulating layer 430 may include a single layer or multiple layers including an inorganic material such as silicon nitride (SiNₓ), silicon oxide (SiOₓ), and/or silicon oxynitride (SiOₓN_{y}). In some embodiments, the second touch insulating layer 430 may include an organic material.

The second touch conductive pattern 440 may be disposed over the second touch insulating layer 430. In an embodiment, the second touch conductive pattern 440 may overlap the pixel definition layer 230. The second touch conductive pattern 440 may not overlap the openings of the pixel definition layer 230. In an embodiment, the second touch conductive pattern 440 may be connected to the first touch conductive pattern 420 through a contact hole included in the second touch insulating layer 430. The second touch conductive pattern 440 may include a conductive material. For example, the second touch conductive pattern 440 may include molybdenum (Mo), aluminum (Al), copper (Cu), titanium (Ti), or the like and may include a single layer or multiple layers including the above material. In an embodiment, the second touch conductive pattern 440 may have a structure (Ti/Al/Ti) in which a titanium layer, an aluminum layer, and a titanium layer are sequentially stacked.

The first touch conductive pattern 420 and the second touch conductive pattern 440 may include a plurality of touch sensing electrodes (not illustrated) for detecting a touch input. In an embodiment, the plurality of touch sensing electrodes may detect an input by a mutual capacitance method. In another embodiment, the plurality of touch sensing electrodes may detect an input by a self capacitance method.

The third touch insulating layer 450 may cover the second touch conductive pattern 440. In an embodiment, the third touch insulating layer 450 may include a single layer or multiple layers including an inorganic material such as silicon nitride (SiNₓ), silicon oxide (SiOₓ), and/or silicon oxynitride (SiOₓN_{y}). In some embodiments, the third touch insulating layer 450 may include an organic material.

The light blocking layer 500 may be disposed over the touch sensor layer 400. Particularly, the light blocking layer 500 may be arranged to cover the third touch insulating layer 450. That is, the lower surface (“low” being in the −z direction) of the light blocking layer 500 may contact the third touch insulating layer 450 including an inorganic material. The lower surface (in the −z direction) of the light blocking layer 500 may surface-contact the third touch insulating layer 450. The lower surface (in the −z direction) of the light blocking layer 500 may directly contact the upper surface (in the +z direction) of the third touch insulating layer 450.

The light blocking layer 500 may include a first upper opening UO1, a second upper opening UO2, a third upper opening UO3, and a sensing upper opening UOS. The first upper opening UO1 may correspond to the first light emitting device ED1. The second upper opening UO2 may correspond to the second light emitting device ED2, and the third upper opening UO3 may correspond to the third light emitting device ED3. The sensing upper opening UOS may correspond to the light receiving device PD.

In other words, the first upper opening UO1 may be disposed over the first light emitting device ED1. The second upper opening UO2 may be disposed over the second light emitting device ED2, and the third upper opening UO3 may be disposed over the third light emitting device ED3. The sensing upper opening UOS may be disposed over the light receiving device PD. That is, the first upper opening UO1 may overlap the first emission area EA1, the second upper opening UO2 may overlap the second emission area EA2, and the third upper opening UO3 may overlap the third emission area EA3. The sensing upper opening UOS may overlap the sensing area SA. The first upper opening UO1 may overlap the first lower opening LO1, the second upper opening UO2 may overlap the second lower opening LO2, and the third upper opening UO3 may overlap the third lower opening LO3. The sensing upper opening UOS may overlap the sensing lower opening LOS.

The area of the first upper opening UO1 may be greater than or equal to the area of the first lower opening LO1. The area of the second upper opening UO2 may be greater than or equal to the area of the second lower opening LO2, and the area of the third upper opening UO3 may be greater than or equal to the area of the third lower opening LO3. The area of the sensing upper opening UOS may be greater than or equal to the area of the sensing lower opening LOS.

The light blocking layer 500 may include a light blocking material. Because the light blocking layer 500 includes the light blocking material, the reflection of external light by metal structures disposed under the light blocking layer 500 may be reduced. However, when necessary, the light blocking layer 500 may include the same material as the pixel definition layer 230 disposed thereunder. However, the disclosure is not limited thereto, and the light blocking layer 500 may include a different material than the pixel definition layer 230. A detailed description of the components and contents of the materials included in the light blocking layer 500 will be described below.

The color filter layer 600 may fill the openings of the light blocking layer 500. The color filter layer 600 may fill the first upper opening UO1, the second upper opening UO2, the third upper opening UO3, and the sensing upper opening UOS. Particularly, the color filter layer 600 may include a first color filter 611, a second color filter 612, a third color filter 613, and a sensing color filter 614. The first color filter 611 may fill the first upper opening UO1, the second color filter 612 may fill the second upper opening UO2, the third color filter 613 may fill the third upper opening UO3, and the sensing color filter 614 may fill the sensing upper opening UOS.

In the case of a display apparatus, in order to reduce the reflection of external light, a color filter may be disposed over each pixel. For example, a green color filter transmitting only green light may be disposed over a pixel emitting green light, a blue color filter transmitting only blue light may be disposed over a pixel emitting blue light, and a red color filter transmitting only red light may be disposed over a pixel emitting red light. Accordingly, when white external light is incident, for example, on the green color filter, the blue light and the red light may be absorbed by the green color filter and green light may be transmitted through the green color filter to be reflected from the pixel electrode. The light reflected off the pixel electrode is transmitted through the green color filter, and emitted to the outside. Thus, in the case of a display apparatus including a color filter, the reflection of external light may decrease to about ⅓ compared to the case where there is no color filter.

Particularly, each of the first color filter 611, the second color filter 612, and the third color filter 613 may have a color corresponding to the light emitted from the emission layer of the light emitting device located thereunder. For example, because the first emission layer 222a of the first light emitting device ED1 located under the first color filter 611 emits green light, the first color filter 611 may be a green color filter; because the second emission layer 222b of the second light emitting device ED2 located under the second color filter 612 emits blue light, the second color filter 612 may be a blue color filter; and because the third emission layer 222c of the third light emitting device ED3 located under the third color filter 613 emits red light, the third color filter 613 may be a red color filter. Moreover, because the light receiving device PD detects green light emitted from the first light emitting device ED1 arranged adjacent thereto, reflected by an object, and then being again incident into the display apparatus 1, the sensing color filter 614 may be a green color filter.

That is, in an embodiment, the first color filter 611 and the sensing color filter 614 may be green color filters that transmit green light. The second color filter 612 may be a blue color filter, and the third color filter 613 may be a red color filter. In other words, the first color filter 611 and the sensing color filter 614 may transmit light of the same wavelength band. Particularly, the first color filter 611 and the sensing color filter 614 may be green color filters that transmit light in an about 495 nm to about 580 nm wavelength band. The second color filter 612 may be a blue color filter that transmits light in an about 380 nm to about 495 nm wavelength band, and the third color filter 613 may be a red color filter that transmits light in an about 580 nm to about 780 nm wavelength band.

The color filter planarization layer 700 may be arranged to cover the color filter layer 600. The color filter planarization layer 700 may be a colorless transparent layer not having a color of the visible light band and may planarize the upper surface of the color filter layer 600. The color filter planarization layer 700 may include a colorless transparent organic material such as an acryl-based resin. For example, the color filter planarization layer 700 may include an organic material such as acryl, benzocyclobutene (BCB), or hexamethyldisiloxane (HMDSO).

The cover window CW may be disposed over the light blocking layer 500. Particularly, the cover window CW may be disposed over the color filter planarization layer 700. The cover window CW may include at least one of glass, sapphire, and plastic. The cover window CW may include, for example, ultra-thin glass (UTG) or colorless polyimide (CPI).

The adhesive member AD may be arranged between the cover window CW and the color filter planarization layer 700. Thus, the adhesive member AD may bond the cover window CW and the color filter planarization layer 700 to each other. The adhesive member AD may include any general one known in the art. The adhesive member AD may include a pressure sensitive adhesive (PSA).

As described above, the light blocking layer 500 may include a light blocking material. Particularly, the light blocking layer 500 may include a first pigment and a second pigment. The first pigment may include a black pigment as a light blocking material. The black pigment may include at least one of a carbon black and an organic black pigment. The organic black pigment may include at least one of a lactam black, a perylene black, and an aniline black.

The second pigment may include a blue pigment. The blue pigment may include at least one of C.I. pigment blues 15, 15:1, 15:2, 15:3, 15:4, and 15:6. For example, the C.I. pigment blue 15:6 may include copper phthalocyanine. In an embodiment, the light blocking layer 500 may include an organic black pigment and a C.I. pigment blue 15:6. The blue pigment may be a pigment that transmits light in an about 380 nm to about 495 nm wavelength band. Particularly, the wavelength of light maximally transmitted by the blue pigment may be about 380 nm to about 495 nm.

As described above, the light emitted from the first light emitting device ED1 may be reflected from the user's fingerprint to be incident on the light receiving device PD and thus the light receiving device PD may detect the reflected light. The light blocking layer 500 includes a light blocking material, and may absorb light reaching the light blocking layer 500. However, because the reflectance at the interface of the light blocking layer 500 is high, a portion of the light reaching the light blocking layer 500 may be reflected at the interface of the light blocking layer 500.

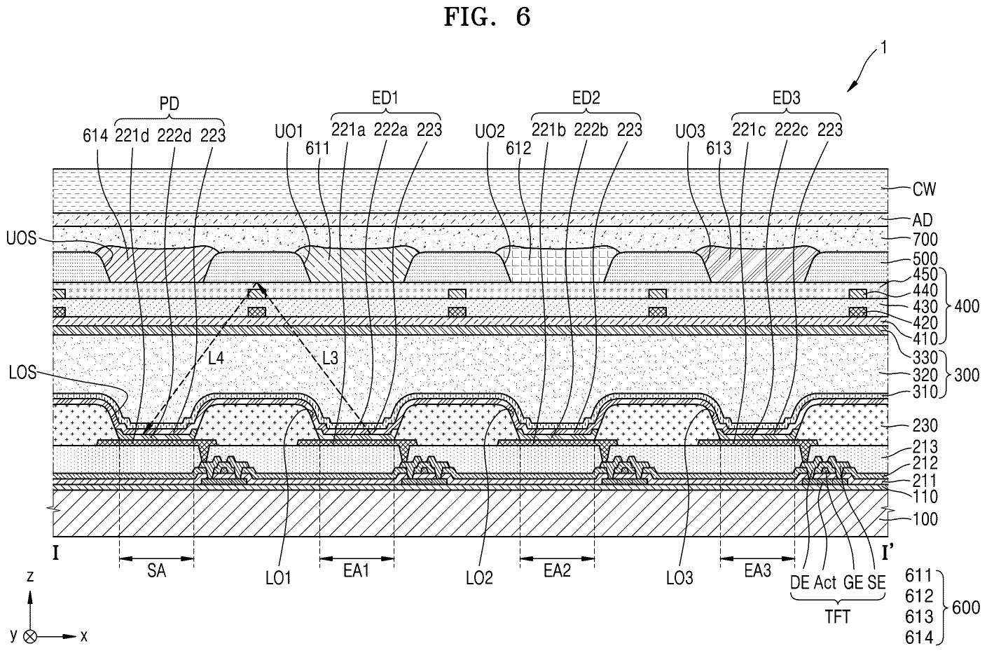

Particularly, the light blocking layer 500 and a layer contacting the lower surface (surface facing the −z direction) of the light blocking layer 500 may form an interface, and the light blocking layer 500 and the layer contacting the lower surface of the light blocking layer 500 may have different refractive indexes. For example, the refractive index of the light blocking layer 500 may be different from the refractive index of the third touch insulating layer 450. Accordingly, as illustrated in FIG. 6, which is a diagram for describing an optical path of light reflected at the interface of a light blocking layer of a display apparatus according to a comparative example, light L3 emitted from the first light emitting device ED1 may reach the lower surface (surface facing the −z direction) of the light blocking layer 500 and may be reflected from the lower surface of the light blocking layer 500. Light L4 reflected off the lower surface of the light blocking layer 500 may be incident on the light receiving device PD, as shown by the arrow in FIG. 6. Due to the internal reflected light being reflected by something other than the user's fingerprint, this reflected light may be treated as noise by the light receiving device PD. With the increased noise level, the detection performance of the light receiving device PD may be compromised.

However, as in the display apparatus according to an embodiment, when the light blocking layer 500 further includes a blue pigment in addition to a black pigment, the internal light reflectance of the light blocking layer 500 may be lowered to reduce the noise of the light receiving device PD. Particularly, a layer including a blue pigment may have a lower reflectance at the interface than a layer including a black pigment. Thus, the internal light reflectance of the light blocking layer 500 may be lower when the light blocking layer 500 further includes a blue pigment in addition to a black pigment than when the light blocking layer 500 includes only a black pigment. Accordingly, the noise of the light receiving device PD may be reduced. Thus, the detection performance of the light receiving device PD may be improved.

In an embodiment, the weight ratio of the black pigment to the blue pigment included in the light blocking layer 500 may be greater than about 10:0 and less than or equal to about 7:3. For example, the weight ratio of the black pigment to the blue pigment may be 9:1, 8:2, or 7:3. When the weight ratio of the black pigment to the blue pigment satisfies the above range, the internal light reflectance of the light blocking layer 500 may be reduced to reduce the noise of the light receiving device PD. When the weight ratio of the black pigment to the blue pigment is greater than 7:3, for example, when the weight ratio of the black pigment to the blue pigment is 6:4, a residue may occur due to the difference in developability between the black pigment and the blue pigment in the process of forming the light blocking layer 500 during the manufacturing process of the display apparatus 1.

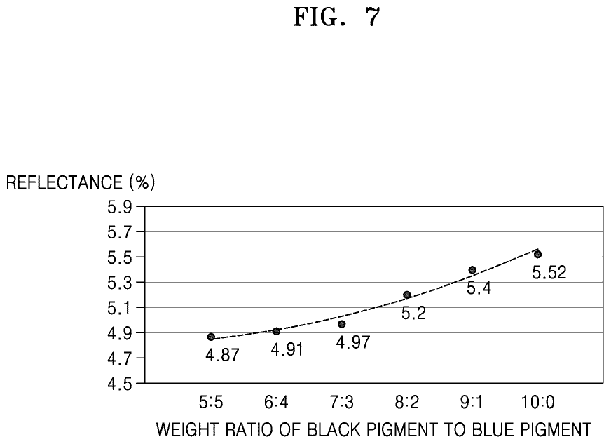

FIG. 7 is a graph illustrating the reflectance of the light blocking layer 500 depending on the weight ratio of the black pigment to the blue pigment included in the light blocking layer 500. The horizontal axis of the graph of FIG. 7 represents the weight ratio of the black pigment to the blue pigment included in the light blocking layer 500. For example, 5:5 means the case where the black pigment is 5 and the blue pigment is 5, 6:4 means the case where the black pigment is 6 and the blue pigment is 4, and 7:3 means the case where the black pigment is 7 and the blue pigment is 3. Also, 8:2 means the case where the black pigment is 8 and the blue pigment is 2, 9:1 means the case where the black pigment is 9 and the blue pigment is 1, and 10:0 means the case where the black pigment is 10 and the blue pigment is 0. The vertical axis of the graph of FIG. 7 represents the reflectance of the light blocking layer 500 in units of percent (%). In FIG. 7, an organic black pigment and a C.I. pigment blue 15:6 are respectively used as the black pigment and the blue pigment.

As illustrated in FIG. 7, as the proportion of the blue pigment included in the light blocking layer 500 increases, the reflectance of the light blocking layer 500 may decrease. Particularly, when the weight ratio of the black pigment to the blue pigment is 10:0, the reflectance of the light blocking layer 500 is 5.52%; when the weight ratio of the black pigment to the blue pigment is 9:1, the reflectance of the light blocking layer 500 is 5.4%; and when the weight ratio of the black pigment to the blue pigment is 8:2, the reflectance of the light blocking layer 500 is 5.2%. When the weight ratio of the black pigment to the blue pigment is 7:3, the reflectance of the light blocking layer 500 is 4.97%; when the weight ratio of the black pigment to the blue pigment is 6:4, the reflectance of the light blocking layer 500 is 4.91%; and when the weight ratio of the black pigment to the blue pigment is 5:5, the reflectance of the light blocking layer 500 is 4.87%. When the weight ratio of the black pigment to the blue pigment is greater than 7:3, even when the proportion of the blue pigment included in the light blocking layer 500 increases, the degree of reduction in the reflectance of the light blocking layer 500 may be slight.

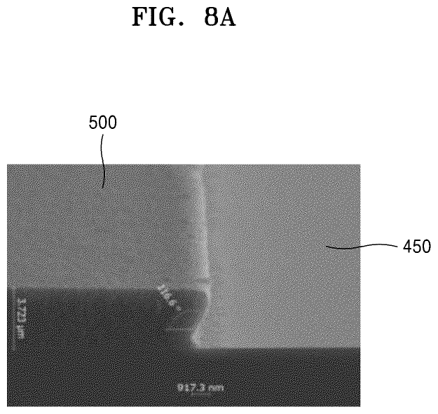

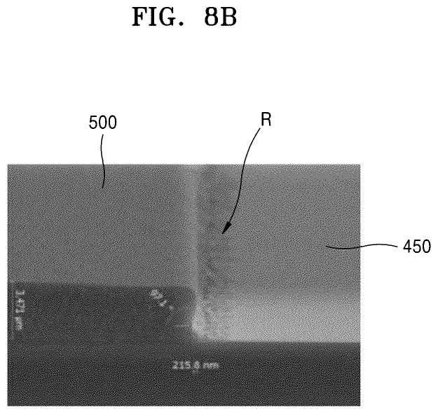

FIG. 8A is a micrograph of the light blocking layer 500 when the weight ratio of the black pigment to the blue pigment included in the light blocking layer 500 is 7:3, and FIG. 8B is a micrograph of the light blocking layer 500 when the weight ratio of the black pigment to the blue pigment included in the light blocking layer 500 is 6:4.

As illustrated in FIG. 8A, when the weight ratio of the black pigment to the blue pigment included in the light blocking layer 500 is 7:3, there is no residue on the third touch insulating layer 450 adjacent to the light blocking layer 500. Similarly to the case where the weight ratio of the black pigment to the blue pigment is 7:3, even when the weight ratio of the black pigment to the blue pigment included in the light blocking layer 500 is 8:2, 9:1, or 10:0, there is no residue on the third touch insulating layer 450 adjacent to the light blocking layer 500.

Moreover, as illustrated in FIG. 8B, when the weight ratio of the black pigment to the blue pigment included in the light blocking layer 500 is 6:4, there is a residue R on the third touch insulating layer 450 adjacent to the light blocking layer 500. Similarly to the case where the weight ratio of the black pigment to the blue pigment is 6:4, even when the weight ratio of the black pigment to the blue pigment included in the light blocking layer 500 is 5:5, there is a residue on the third touch insulating layer 450 adjacent to the light blocking layer 500. That is, when the weight ratio of the black pigment to the blue pigment is greater than 7:3, a residue R occurs due to the difference in developability between the black pigment and the blue pigment in the process of forming the light blocking layer 500 during the manufacturing process of the display apparatus 1.

In an embodiment, the light blocking layer 500 may further include a third pigment. The third pigment may include a violet pigment. The violet pigment may include at least one of C.I. pigment violets 1, 19, 23, 27, 29, 30, 32, 37, 40, 42, and 50. For example, the C.I. pigment violet 23 may include ethyl carbazole dioxazine. In an embodiment, the light blocking layer 500 may further include the C.I. pigment violet 23.

Because the light blocking layer 500 further includes a violet pigment, the wavelength absorbed by the light blocking layer 500 may be adjusted. When the light blocking layer 500 further includes a violet pigment, light in a different wavelength band may be absorbed than when the light blocking layer 500 includes only a blue pigment. That is, the violet pigment absorbs a portion of the light that is not absorbed by the blue pigment. Accordingly, the light blocking layer 500 may absorb light in a wider wavelength band. Thus, the light blocking layer 500 may absorb more light reaching the light blocking layer 500, may further reduce the internal reflected light reaching the light receiving device PD, and may effectively reduce the noise.

In an embodiment, the light blocking layer 500 may further include an acryl-based binder resin or a cardo-based binder resin. For example, the light blocking layer 500 may include a black pigment and a blue pigment and may further include an acryl-based binder resin or a cardo-based binder resin. In another embodiment, the light blocking layer 500 may include a black pigment, a blue pigment, and a violet pigment and may further include an acryl-based binder resin or a cardo-based binder resin.

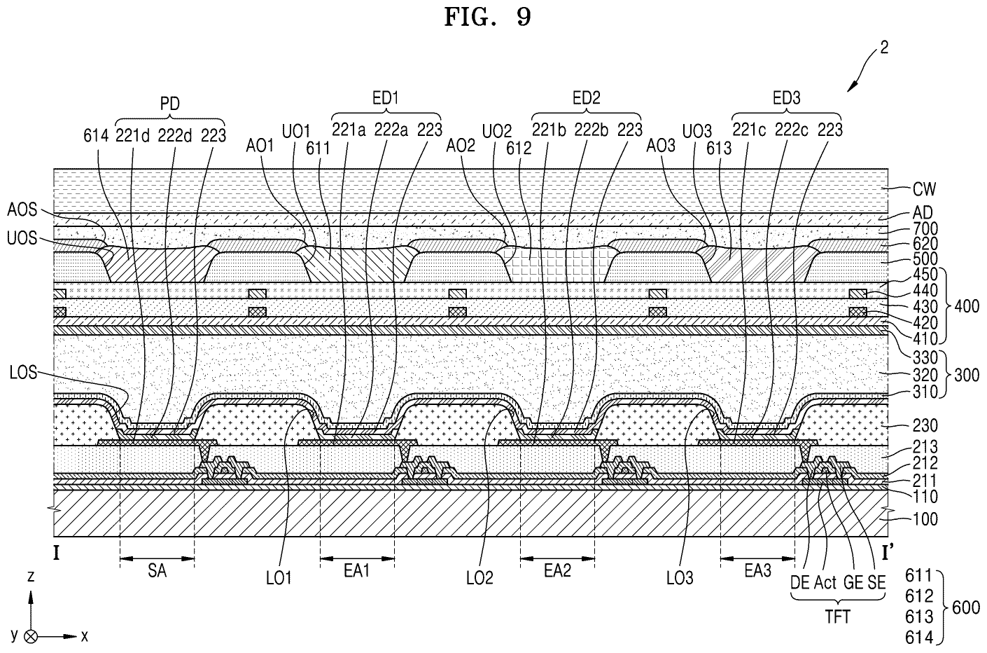

FIG. 9 is a cross-sectional view schematically illustrating a portion of a display apparatus 2 according to another embodiment. Because the display apparatus 2 according to the present embodiment is similar to the display apparatus 1 described above with reference to FIG. 5 or the like, the following description will focus on the difference from the display apparatus 1 described above with reference to FIG. 5 or the like. In FIG. 9, like reference numerals as those in FIG. 5 or the like denote like members, and thus, redundant descriptions thereof will be omitted for conciseness.

The display apparatus 1 according to the embodiment described above with reference to FIG. 5 or the like may include the substrate 100, the transistor TFT, the first light emitting device ED1, the second light emitting device ED2, the third light emitting device ED3, the light receiving device PD, the encapsulation layer 300, the touch sensor layer 400, the light blocking layer 500, the color filter layer 600, the color filter planarization layer 700, the adhesive member AD, and the cover window CW. As illustrated in FIG. 9, the display apparatus 2 according to the present embodiment may also include the substrate 100, the transistor TFT, the first light emitting device ED1, the second light emitting device ED2, the third light emitting device ED3, the light receiving device PD, the encapsulation layer 300, the touch sensor layer 400, the light blocking layer 500, the color filter layer 600, the color filter planarization layer 700, the adhesive member AD, and the cover window CW.

As illustrated in FIG. 9, the display apparatus 2 according to the present embodiment may further include an auxiliary layer 620.

The auxiliary layer 620 may be disposed on the light blocking layer 500. For example, the auxiliary layer 620 may be arranged between the light blocking layer 500 and the color filter planarization layer 700. Particularly, the auxiliary layer 620 may include a first auxiliary opening AO1, a second auxiliary opening AO2, a third auxiliary opening AO3, and a sensing auxiliary opening AOS. The first auxiliary opening AO1 may be positioned above the first emission area EA1, the second auxiliary opening AO2 may be positioned above the second emission area EA2, and the third auxiliary opening AO3 may be positioned above the third emission area EA3. The sensing auxiliary opening AOS may be positioned above the sensing area SA. The first auxiliary opening AO1 may be positioned above the first lower opening LO1, the second auxiliary opening AO2 may be positioned above the second lower opening LO2, and the third auxiliary opening AO3 may be positioned above the third lower opening LO3. The sensing auxiliary opening AOS may be positioned above the sensing lower opening LOS. In other words, the first auxiliary opening AO1 may be vertically aligned with the first upper opening UO1, the second auxiliary opening AO2 may be vertically aligned with the second upper opening UO2, and the third auxiliary opening AO3 may be vertically aligned with the third upper opening UO3. The sensing auxiliary opening AOS may be vertically aligned with the sensing upper opening UOS. Two elements being “vertically aligned,” as used herein, indicates that an imaginary straight line extending through the cross-sectional view of FIG. 9 orthogonally to the upper surface of the substrate 100 would extend through a center region of both elements.

The area of the first auxiliary opening AO1 may be greater than or equal to the area of the first lower opening LO1. The area of the second auxiliary opening AO2 may be greater than or equal to the area of the second lower opening LO2, and the area of the third auxiliary opening AO3 may be greater than or equal to the area of the third lower opening LO3. The area of the sensing auxiliary opening AOS may be greater than or equal to the area of the sensing lower opening LOS.

Moreover, the auxiliary layer 620 may be a color filter that absorbs light in the same wavelength band as the first color filter 611 or the third color filter 613. For example, the auxiliary layer 620 may be a color filter that absorbs light in an about 380 nm to about 495 nm wavelength band. In an embodiment, the auxiliary layer 620 may be a green color filter that transmits light in an about 495 nm to about 580 nm wavelength band or may be a red color filter that transmits light in an about 580 nm to about 780 nm wavelength band.

As described above, the light blocking layer 500 may include a first pigment and a second pigment. For example, the light blocking layer 500 may further include a blue pigment in addition to a black pigment. In this case, because the amount of the black pigment included in the light blocking layer 500 decreases and the amount of the blue pigment included therein increases, the amount of light in the wavelength band transmitted by the blue pigment may increase. For example, the amount of light in an about 380 nm to about 495 nm wavelength band transmitted by the light blocking layer 500 may increase.

However, the display apparatus 2 according to the present embodiment may include the auxiliary layer 620 disposed over the light blocking layer 500, and the auxiliary layer 620 may be a green color filter that transmits light in an about 495 nm to about 580 nm wavelength band or a red color filter capable of transmitting light in an about 580 nm to about 780 nm wavelength band. That is, the auxiliary layer 620 may absorb light in an about 380 nm to about 495 nm wavelength band. Accordingly, even when light in an about 380 nm to about 495 nm wavelength band is transmitted through the light blocking layer 500, because the light is absorbed by the auxiliary layer 620, reflection of external light by the metal structures disposed under the light blocking layer 500 may be reduced.

As described above, according to an embodiment, a display apparatus including a light receiving device with improved detection performance may be implemented. However, the scope of the disclosure is not limited to these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a first light emitting device and a light receiving device disposed on the substrate and positioned adjacent to each other; and
a light blocking layer disposed on the first light emitting device and the light receiving device and including a first upper opening vertically aligned with the first light emitting device and a sensing upper opening vertically aligned with the light receiving device,
wherein the light blocking layer comprises a black pigment and a blue pigment.

2. The display apparatus of claim 1, wherein a weight ratio of the black pigment to the blue pigment is greater than about 10:0 and less than or equal to about 7:1.

3. The display apparatus of claim 1, wherein the black pigment comprises at least one of a carbon black and an organic black pigment.

4. The display apparatus of claim 1, wherein the blue pigment comprises at least one of C.I. pigment blues 15, 15:1, 15:2, 15:3, 15:4, and 15:6.

5. The display apparatus of claim 1, wherein the light blocking layer further comprises a violet pigment, and
the violet pigment comprises at least one of C.I. pigment violets 1, 19, 23, 27, 29, 30, 32, 37, 40, 42, and 50.

6. The display apparatus of claim 1, further comprising a touch sensor layer arranged between the first light emitting device and the light receiving device and the light blocking layer and comprising a plurality of touch conductive patterns and a plurality of touch insulating layers.

7. The display apparatus of claim 6, wherein a lower surface of the light blocking layer contacts a layer comprising an inorganic material.

8. The display apparatus of claim 7, wherein the lower surface of the light blocking layer contacts a touch insulating layer included in the touch sensor layer.

9. The display apparatus of claim 6, further comprising an encapsulation layer arranged between the first light emitting device and the touch sensor layer and comprising at least one inorganic layer and at least one organic layer.

10. The display apparatus of claim 1, further comprising:
a first color filter in the first upper opening; and
a sensing color filter in the sensing upper opening.

11. The display apparatus of claim 10, wherein the first color filter and the sensing color filter transmit light in a same wavelength band.

12. The display apparatus of claim 11, wherein the first color filter and the sensing color filter transmit light in an about 495 nm to about 580 nm wavelength band.

13. The display apparatus of claim 1, further comprising an auxiliary layer disposed on the light blocking layer and including a first auxiliary opening vertically aligned with the first upper opening and a sensing auxiliary opening vertically aligned with the sensing upper opening.

14. The display apparatus of claim 13, wherein the auxiliary layer absorbs light in an about 380 nm to about 495 nm wavelength band.

15. The display apparatus of claim 13, wherein the auxiliary layer transmits light in an about 495 nm to about 580 nm wavelength band or transmits light in an about 580 nm to about 780 nm wavelength band.

16. The display apparatus of claim 1, wherein the first light emitting device comprises a pixel electrode, an emission layer disposed on the pixel electrode, and an opposite electrode disposed on the emission layer, and
the light receiving device comprises a sensing electrode, an active layer disposed on the sensing electrode, and an opposite electrode arranged on the active layer.

17. The display apparatus of claim 16, further comprising a pixel definition layer disposed on the pixel electrode and the sensing electrode and including a first lower opening vertically aligned with the first upper opening and a sensing lower opening vertically aligned with the sensing upper opening.

18. The display apparatus of claim 1, further comprising:
a second light emitting device and a third light emitting device disposed on the substrate, and
the first light emitting device, the second light emitting device, and the third light emitting device are positioned apart from each other in a plan view.

19. The display apparatus of claim 18, wherein the first light emitting device emits light in an about 495 nm to about 580 nm wavelength band,
the second light emitting device emits light in an about 380 nm to about 495 nm wavelength band,
the third light emitting device emits light in an about 580 nm to about 780 nm wavelength band, and
the light receiving device detects light in an about 495 nm to about 580 nm wavelength band.

20. The display apparatus of claim 1, further comprising a cover window disposed on the light blocking layer.
